(19) United States
(12) Patent Application Publication
(10) Pub. No.: US 2007/0080455 A1
(43) Pub. Date: Apr. 12, 2007

(54) SEMICONDUCTORS AND METHODS OF MAKING

(75) Inventors: Donna S. Zupanski-Nielsen, Yorktown Heights, NY (US); William F. Landers, Wappingers Falls, NY (US); Ian D. Melville, Highland, NY (US); Roger A. Quon, Rhinebeck, NY (US); Timothy H. Daubenspeck, Colchester, VT (US); Kamalesh K. Srivastava, Wappingers Falls, NY (US); Mary C. Cullinan-Scholl, Hopewell Junction, NY (US); Lawrence A. Clevenger, LaGrangeville, NY (US); Christopher D. Muzzy, Burlington, VT (US)

Correspondence Address: OHLANDT, GREELEY, RUGGIERO & PERLE, LLP, ONE LANDMARK SQUARE, 10TH FLOOR, STAMFORD, CT, 06901, US

(73) Assignee: INTERNATIONAL BUSINESS MACHINES CORPORATION, Armonk, NY (US)

(21) Appl. No.: 11/163,235

(22) Filed: Oct. 11, 2005

(51) Int. Cl. H01L 23/48; H01L 21/44

(52) U.S. Cl. 257/738; 438/612; 438/614; 257/779

(57) ABSTRACT

A semiconductor having an insulating layer, a contact pad, a via, and a sacrificial dielectric cap is provided. The contact pad is embedded in the insulating layer, where the contact pad has a top metal layer of copper. The via creates an opening over the top metal layer. The sacrificial dielectric cap is over at least the top metal layer.

### BACKGROUND OF INVENTION

The present disclosure relates to semiconductors. More particularly, the present disclosure relates to semiconductors having a sacrificial cap over exposed copper interconnects and methods of making such semiconductors.

Increased levels of integration in the silicon transistor technology have facilitated the migration to semiconductors having smaller and smaller integrated circuits (IC) thereon. There has also been a push to integrate varied functions into a single compact system, known as the system-on-a-chip (SOC) approach. Simply stated, the SOC approach attempts to integrate as many different device functionalities on the same semiconductor so that a single large semiconductor or chip can provide a variety of functions to the end user. Although conceptually very attractive, such an approach is practically daunting for a variety of reasons.

An attractive alternative to the SOC approach is the system-on-a-package (SOP) approach. Here, a number of semiconductors, each optimized for its unique function, are combined on a first level carrier that interconnects them and allows the resulting package to function as a single system. The level of interconnection and input-output (I/O) density required in such a package is expected to have interconnect levels (typically wiring and vias) on from between about 500 to 20,000 nanonmeters (nm) pitch.

It is common for the semiconductors used in the SOP approach to be manufactured in different factories or manufacturing lines specially tailored to produce that specific semiconductor. After manufacture, the semiconductors are shipped to an assembly location, where a plurality of different semiconductors are combined on the first level carrier.

One conventional method for mounting semiconductors to the first level carrier is called “controlled collapse chip connect” (C4). In fabricating a C4 package, the terminals (generally called a “contact pad”) on the surface of the semiconductor are soldered directly to the contact pad on the surface of the first level carrier using reflowable solder balls. In this manner, the semiconductors disposed on the first level carrier are interconnected and, thus, allow the resulting package to function as a single system.

As discussed above, semiconductors mounted on the first level carrier during the SOP approach are commonly manufactured in different factories or on different manufacturing lines specially tailored to produce the specific semiconductors. The contact pad of each semiconductor need to be protected from, for example, oxidation between the manufacture of the semiconductor and the mounting of the semiconductor on the carrier.

Currently, semiconductors for SOP are made with contact pads having a top metal layer of aluminum-copper (AlCu) covering the underlying Cu layers, which form the contact pads. This top metal layer simultaneously acts as a wiring level for the contact pads during C4 connection and prevents oxidation of the underlying Cu layers after manufacture of the chip but before C4 connection. The top metal layer of AlCu forms a very tough oxide that forms a very resistant metal coating.

Unfortunately, the application of the top metal layer of AlCu requires costly and time consuming lithography processes (e.g., masking layers). In addition, the top metal layer of AlCu increases the resistivity of the semiconductor's contact pads. Specifically, the additional top metal layer of AlCu increases the resistance-capacitance (RC) time delay of the underlying Cu layer by about 37%, which is the gating factor in limiting digital circuit performance. Thus, it has been determined by the present disclosure that the top metal layer of AlCu on semiconductors for the SOP approach increases the overall cost and reduces the overall performance of the semiconductor and resulting system.

Accordingly, semiconductors and methods of making such semiconductors that overcome, mitigate, and/or alleviate one or more of the aforementioned and other drawbacks and deficiencies of the prior art semiconductors are desired.

### BRIEF DESCRIPTION OF THE INVENTION

Semiconductors and methods of making are provided, which include one or more contact pads having a top metal layer of copper (Cu) and a sacrificial dielectric cap sealing this top metal layer.

Semiconductors and methods of making such semiconductors are provided that includes depositing a sacrificial dielectric cap material over Cu contact pads, where the cap can be removed during cleaning processes normally associated with C4 processing.

In one embodiment, a semiconductor having an insulating layer, a contact pad, a via, and a sacrificial dielectric cap is provided. The contact pad is embedded in the insulating layer, where the contact pad has a top metal layer of copper. The via creates an opening over the top metal layer. The sacrificial dielectric cap is over at least the top metal layer.

In another embodiment, a semiconductor having an insulating layer, a contact pad, a via, a dielectric cap, and a reflowable solder ball is provided. The contact pad is embedded in the insulating layer, where the contact pad has a top metal layer of copper. The via is defined in the insulating layer to create an opening over the top metal layer. The dielectric cap is on the insulating layer and the reflowable solder ball is in the via in electrical communication with the top metal layer.

A method of making a semiconductor is also provided. The method includes defining interconnect wiring having a contact pad, the contact pad having a top metal layer of copper; depositing an insulating layer over the contact pad; patterning the insulating layer with a via to create an opening over the top metal layer; depositing a sacrificial dielectric layer on at least the top metal layer; depositing a stress-relief layer on the sacrificial dielectric cap; and developing away the stress-relief layer to define an exposed area of the sacrificial dielectric cap, the exposed area comprising a first region on top of the top metal layer.

The above-described and other features and advantages of the present disclosure will be appreciated and understood by those skilled in the art from the following detailed description, drawings, and appended claims.

### BRIEF DESCRIPTION OF THE DRAWINGS

FIG. 1 is a schematic depiction of a cross-section of an exemplary embodiment of a semiconductor for use with the present disclosure;

FIG. 2 is a schematic depiction of the semiconductor of FIG. 1, after application of a sacrificial dielectric cap according to the present disclosure;

FIG. 3 is a schematic depiction of the semiconductor of FIG. 2, after application of a stress-relief layer;

FIG. 4 is a schematic depiction of the semiconductor of FIG. 3, after removal of the stress-relief layer in one or more locations;

FIG. 5 is a schematic depiction of the semiconductor of FIG. 4, after exposure to a typical C4 cleaning process;

FIG. 6 is a schematic depiction of the semiconductor of FIG. 5, after application of BLM using a typical C4 processing step;

FIG. 7 is a schematic depiction of the semiconductor of FIG. 6, after application of solder balls using a typical C4 processing step; and

FIG. 8 is a schematic depiction of the semiconductor of FIG. 7, after removal of BLM and application of reflowable solder balls using typical C4 processing steps.

### DETAILED DESCRIPTION OF THE INVENTION

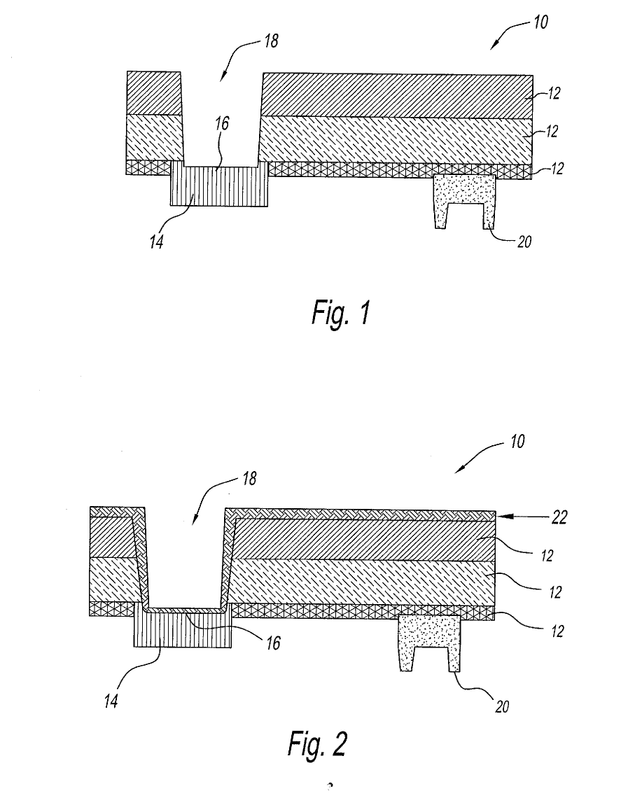

Referring to the drawings and in particular to FIG. 1, a schematic depiction of a cross-section of a semiconductor according to the present disclosure is illustrated by way of reference numeral 10. Semiconductor 10 finds use in the system-on-a-package approach. Namely, semiconductor 10 is configured for combination with other semiconductors on a first level carrier (not shown) to allow the resulting package to function as a single system.

Semiconductor 10 can be any type of semiconductor. In the illustrated embodiment semiconductor 10 includes one or more insulating layers 12 deposited over interconnect wiring (not shown) having one or more one or more contact pads 14 (only one shown). Advantageously, contact pad 14 has a top metal layer 16 of copper. Insulating layers 12 are patterned with one or more vias 18 to create an opening over top metal layer 16. Layers 12 can include oxide layers, nitride layers, and other common semiconductor layers.

In some embodiments, semiconductor 10 can include a device 20 such as, but not limited to, a fuse, a resistor, a capacitor, a light emitting diode, and other common semiconductor devices.

Advantageously, it has been found that the aluminum-copper (AlCu) layer required by the prior art is not needed. Rather and referring to FIG. 2, semiconductor 10 is advantageously provided with a dielectric cap 22. Cap 22 is deposited at least over top metal layer 16 of contact pad 14 and, preferably, over substantially all of the surface of semiconductor 10 having the contact pad 14.

In this manner, cap 22 removes the masking steps necessary to apply the top AlCu layer to the contact pad of the prior art and, thus, lowers the time and expense of making semiconductor 10. In addition, the use of cap 22 decreases the resistance-capacitance (RC) time delay of semiconductor 10 as compared to those having an AlCu layer applied to contact pad 14.

It should be recognized that the dielectric cap present disclosure is described by way of example in use with semiconductor 10, which has contact pad 14 and via 18 defined on one side of the semiconductor. Of course, it is contemplated by the present disclosure for dielectric cap 22 to find use on semiconductors having one or more contact pads 14 and/or vias 18 on multiple sides of the semiconductor.

Cap 22 is a sacrificial cap that protects the exposed top metal copper layer 16 of contact pad 14 before interconnection of the contact pad with a first level carrier (not shown). As used herein, the term sacrificial means that at least the portion of the cap 22 that covers the top metal layer 16 of contact pad 14 is removed during further processing of the semiconductor 10.

The material and thickness of cap 22 are selected so that the cap is easily removed by cleaning process that is typical of the C4 processing as will be discussed herein below.

Cap 22 is an insulating material that provides a diffusion or moisture barrier to contact pad 14 to prevent oxidation of top metal copper layer 16 of the contact pad. Cap 22 made of a material that adheres to top metal copper layer 16 of contact pad 14, as well as to layer 12.

For example, cap 22 can be made of nitride, a layer composed of Si, O, C, N, and any combinations thereof. In a preferred embodiment, cap 22 is Si_{w} 0ₓ, N_{y}, C_{z}, that can be applied to semiconductor 10 using known chemical vapor deposition (CVD) processes. Of course, other methods of applying cap 22 such as, but not limited to, physical vapor deposition (PVD), printing, dip coating, spin coating, and the like are contemplated by the present disclosure. Advantageously, the deposition of cap 22 also removes the need for the costly and time consuming lithography steps needed by the prior art for the application of the AlCu top layer.

The thickness of cap 22 is preferably sufficient to form a continuous layer across semiconductor 10. However, the thickness of cap 22 is preferably minimized so that the C4 cleaning process is unaffected (e.g., lengthened) as compared to the same cleaning process for the prior art semiconductors having the AlCu layer applied to the top metal copper layer of the pad.

In the example where cap 22 is made of Si_{w} 0ₓ, N_{y}, C_{z}, the cap has a thickness of at least about 100 angstroms (A), which is believed to be the thickness needed for a continues layer of the cap. However, Nblok cap 22 has a thickness of less than about 600 A, which is believed to be the thickness needed to prevent lengthening of the typical C4 cleaning process. In a preferred embodiment, Nblok cap 22 has a thickness of about 200A. Thus, it is contemplated by the present disclosure for cap 22 that comprises Nblok to have a thickness of between about 100 A and 600 A and any subranges therebetween, with about 200 A being most preferred.

Advantageously, semiconductor 10 having cap 22 as illustrated in FIG. 2 is completed and can be shipped for further C4 processing to connect contact pad 14 to a first level package. Also, semiconductor 10 has about 37% lower resistance-capacitance (RC) time delay as compared to prior art semiconductors having the additional layer of AlCu over the top metal copper layer of contact pad 14.

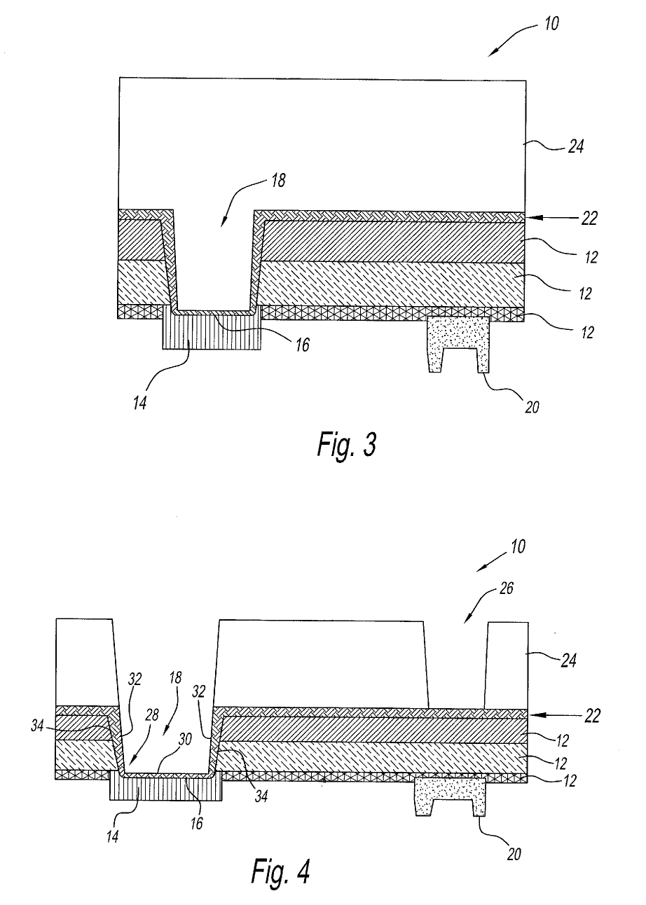

In some designs, semiconductor 10 can also include a stress-relief layer 24 deposited over cap 22 as shown in FIGS. 3 and 4. Stress-relief layer 24 can protect one or more portions of semiconductor 10 after manufacture of the semiconductor and before assembly with the first level packaging. Stress-relief layer 24 can comprise a photosensitive polymer such as, but not limited to polyimide. Preferably, stress-relief layer 24 is developed away from at least via 18 to define one or more exposed areas 28 of cap 22. Exposed area 28 of cap 22 includes a first region 30 on top of metal layer 16 and a second region 32 defined at walls 34 of via 18.

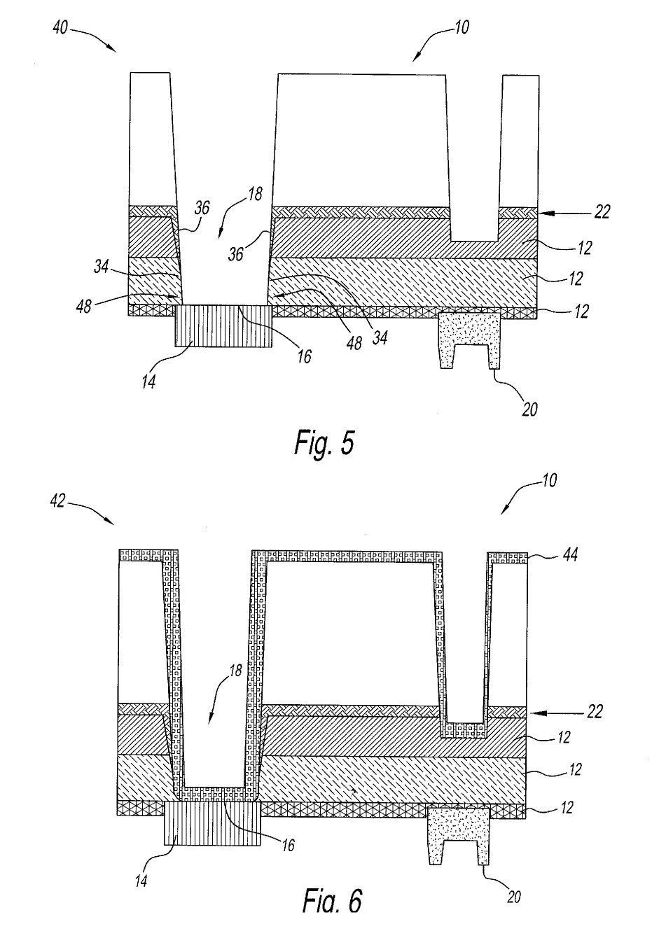

The use of semiconductor 10 according to the present disclosure during typical C4 processing steps is illustrated with reference to FIGS. 5 through 8.

Preparation of semiconductor 10 for interconnection with a first level package includes at least one cleaning process 40. Semiconductor 10 is illustrated in FIG. 5 after exposure to cleaning process 40. Cleaning process 40 is sufficient to remove at least first region 30 of cap 22. In one embodiment, cleaning process 40 is sufficient to remove cap 22 from both first and second regions 30, 32. Cleaning process 40 can include argon sputter cleaning or reactive ion etching (RIE).

After cleaning process 40, semiconductor 10 is exposed to a metal deposition step 42 for depositing a ball limiting metallurgy (BLM) metal 44 on the semiconductor as shown in FIG. 6.

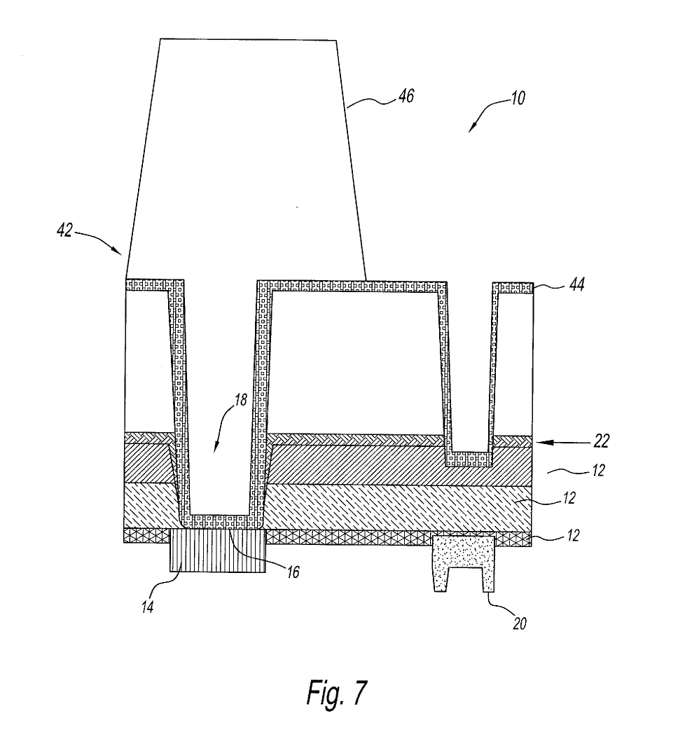

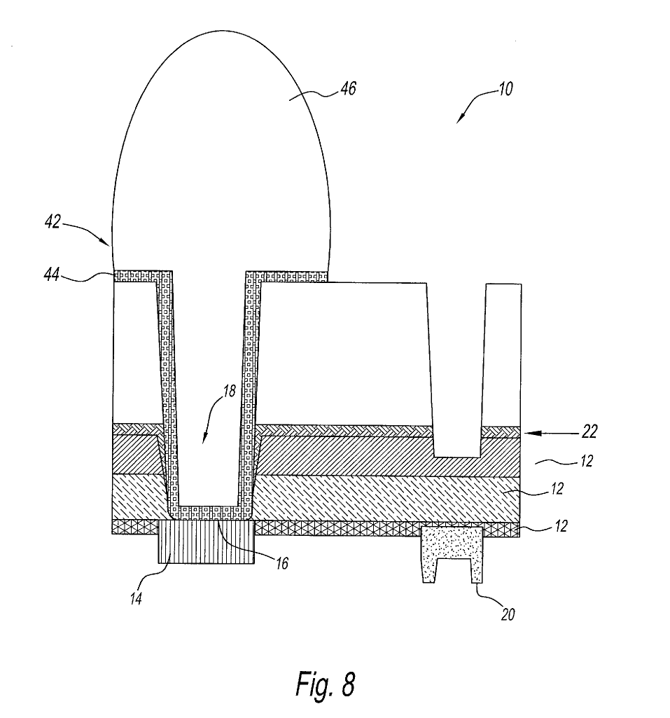

Next, semiconductor 10 has a reflowable solder ball 46 deposited to BLM metal 44 in via 18 as shown in FIG. 7. After deposition of solder ball 46 on BLM metal 44, the exposed BLM metal is removed and the solder ball is reflowed as shown in FIG. 8. In this manner, reflowable solder ball 46 is in electrical communication with top metal copper layer 16 of contact pad 14 through BLM metal 44. At this point, semiconductor 10 is completed and is ready for interconnection of reflowable solder ball 46 to the first level packaging.

Referring again to FIG. 5, it can be desirable, in some embodiments, for cleaning process 40 to remove only part of second region 32 of cap 22 from walls 34 of via 18 so that at least a portion 36 of the cap remains along the wall. Without being limited to any particular theory, it is believed that second region 32 which remains along walls 34, at worst has no impact on the adhesion of BLM metal 44 in via 18 and, in some circumstances improves adhesion between the BLM metal and the via. For example, adhesion between BLM metal 44 and top metal copper layer 16 of contact pad 14 can be negatively impacted by thermal and mechanical stresses induced during use of semiconductor 10. It is believed that adhesion may be promoted by leaving second region 32 along wall 34 to spread the stresses away from corners 48 of contact pad 14 where BLM metal 44 is adhered to top metal layer 16. Thus, it is believed that second region 32 of cap 22 can promote adhesion by redistributing the stress to prevent failure of the adhesion.

Accordingly, sacrificial cap 22 of semiconductor 10 acts as a diffusion or moisture barrier to the top metal copper layer 16 of contact pad 14 to prevent oxidation of the Cu before C4 interconnection. In this manner, the top metal copper layer 16 of contact pad 14 itself makes electrical connection with BLM metal 44, without the resistance increasing AlCu layer of the prior art.

The terms “first”, “second”, “third”, “upper”, “lower”, and the like may be used herein to modify various elements. These modifiers do not imply a spatial, sequential, or hierarchical order to the modified elements unless specifically stated.

While the present disclosure has been described with reference to one or more exemplary embodiments, it will be understood by those skilled in the art that various changes may be made and equivalents may be substituted for elements thereof without departing from the scope of the present disclosure. In addition, many modifications may be made to adapt a particular situation or material to the teachings of the disclosure without departing from the scope thereof. Therefore, it is intended that the present disclosure not be limited to the particular embodiment(s) disclosed as the best mode contemplated, but that the disclosure will include all embodiments falling within the scope of the appended claims.

What is claimed is:

1. A semiconductor comprising:
an insulating layer;
a contact pad embedded in said insulating layer, said contact pad having a top metal layer of copper;
a via in said insulating layer to create an opening over said top metal layer; and
a sacrificial dielectric cap over at least said top metal layer.

2. The semiconductor of claim 1, wherein said sacrificial dielectric cap has a thickness of at least about 100 angstroms.

3. The semiconductor of claim 1, wherein said sacrificial dielectric cap has a thickness of less than about 600 A.

4. The semiconductor of claim 1, wherein said sacrificial dielectric cap has a thickness of about 200 A.

5. The semiconductor of claim 1, wherein said sacrificial dielectric cap comprises a material selected from the group consisting of nitride, Si_{w} 0ₓ, N_{y}, C_{z} and any combinations thereof.

6. The semiconductor of claim 1, wherein said sacrificial dielectric cap is over said insulating layer and said via.

7. The semiconductor of claim 6, further comprising a stress-relief layer over said sacrificial dielectric cap.

8. The semiconductor of claim 7, wherein said stress-relief layer is developed away to define an exposed area of said sacrificial dielectric cap at said top metal layer.

9. A semiconductor comprising:
an insulating layer;
a contact pad embedded in said insulating layer, said contact pad having a top metal layer of copper;
a via defined in said insulating layer to create an opening over said top metal layer;
a dielectric cap on said insulating layer; and
a reflowable solder ball in said via in electrical communication with said top metal layer.

10. The semiconductor of claim 9, wherein said dielectric cap has a thickness of between about 100 angstroms and about 600 A.

11. The semiconductor of claim 9, wherein said dielectric cap has a thickness of about 200 A.

12. The semiconductor of claim 9, wherein said dielectric cap comprises a material selected from the group consisting of nitride, Si_{w} 0ₓ, N_{y}, C_{z}, and any combinations thereof.

13. The semiconductor of claim 9, wherein said dielectric cap extends on at least a portion of said via.

14. The semiconductor of claim 9, further comprising a ball-limiting metallurgy layer between said reflowable solder ball and said top metal layer, said ball-limiting metallurgy layer placing said reflowable solder ball in direct electrical communication with said top metal layer.

15. A method of making a semiconductor, comprising:
defining interconnect wiring having a contact pad, said contact pad having a top metal layer of copper;
depositing an insulating layer over said contact pad;
patterning said insulating layer with a via to create an opening over said top metal layer;
depositing a sacrificial dielectric layer on said insulating layer, said via, and said top metal layer;
depositing a stress-relief layer on said sacrificial dielectric cap; and
developing away said stress-relief layer to define an exposed area of said sacrificial dielectric cap, said exposed area comprising a first region on top of said top metal layer.

16. The method of claim 15, further comprising exposing the semiconductor to at least one a cleaning process sufficient to remove said first region.

17. The method of claim 16, wherein said at least one cleaning process comprises argon sputter cleaning or reactive ion etching.

18. The method of claim 16, further comprising depositing a reflowable solder ball so that said reflowable solder ball is in electrical communication with said top metal layer.

19. The method of claim 15, wherein exposed area further comprises a second region of said sacrificial dielectric layer, said second region being defined at a wall of said via.

20. The method of claim 19, wherein said at least one a cleaning process is sufficient to remove at least part of said second region.
